(19) United States
(12) Patent Application Publication
(10) Pub. No.: US 2013/0299990 A1
(43) Pub. Date: Nov. 14, 2013

(54) SINGLE METAL DAMASCENE STRUCTURE AND METHOD OF FORMING THE SAME

(71) Applicant: Chien-Fu Chen, Singapore (SG)

(72) Inventor: Chien-Fu Chen, Singapore (SG)

(73) Assignee: United Microelectronics Corp., Hsinchu (TW)

(21) Appl. No.: 13/471,209

(22) Filed: May 14, 2012

(51) Int. Cl. H01L 23/522; H01L 21/768

(52) U.S. Cl. 257/751; 438/643; 257/E23.145; 257/E21.584

(57) ABSTRACT

A single metal damascene structure including an insulating layer, a metal filling layer and a barrier layer is provided. The insulating layer has an opening therein, and the metal filling layer is positioned in the opening. The barrier layer is located between the filling metal layer and the insulating layer. The material of the barrier layer includes an alloy, and the ally includes a copper element and at least one another metal.

### BACKGROUND OF THE INVENTION

1. Field of Invention

The present invention relates to a single metal damascene structure and a method of forming the same.

2. Description of Related Art

A contact process is included between the front-end-of-line and back-end-of line process stages in the semiconductor device manufacture, so as to form contacts electrically connecting the device on the substrate and the metal lines.

In the contact process, an interlayer dielectric layer is formed on the substrate having the device formed thereon, a contact opening is thereafter formed in the dielectric layer through photolithography and etching processes, and a tungsten plug is then formed in the contact opening.

With minimization of the device, the resistance of the tungsten plug is increased as the dimension thereof is reduced, and the front-end performance degradation occurs. When the copper plug is used to replace the tungsten plug, the contact resistance can be reduced but the copper diffusion problem is caused thereby.

### SUMMARY OF THE INVENTION

The present invention provides a single metal damascene structure to reduce the contact resistance, prevent the metal from diffusing and enhance the device reliability.

The present invention further provides a method of forming a single metal damascene structure, in which a barrier layer can be formed with simple process steps, metal diffusion can be avoided, and the device reliability can be enhanced.

The present invention provides a single metal damascene structure including an insulating layer, a metal filling layer and a barrier layer. The insulating layer has an opening therein. The metal filling layer is located in the opening. The barrier layer is located between the metal filling layer and the insulating layer. The barrier layer includes an alloy, and the alloy includes a copper element and at least one another metal.

According to an embodiment of the present invention, the at least one another metal includes a manganese (Mn) element, an aluminium (Al) element or an alloy thereof.

According to an embodiment of the present invention, the opening includes a contact opening or a via opening.

According to an embodiment of the present invention, the metal filling layer includes a tungsten (W) element, a copper element or an alloy thereof.

According to an embodiment of the present invention, the single metal damascene structure further includes a conductive region on a substrate, and the conductive region electrically contacts the barrier layer.

According to an embodiment of the present invention, the conductive region includes a metal silicide layer or a doped region.

According to an embodiment of the present invention, the single metal damascene structure further includes a seed layer disposed between the barrier layer and the metal filling layer.

According to an embodiment of the present invention, the seed layer includes an alloy containing Cu and at least one of Al, Mg, Be, Ca, Sr, Ba, Sc, Y, La, U,

Pr, Nd, Sm, Eu, Gd, Tb, Dy, Ho, Er, Tm, Yb, Lu, Hf, V, Nb, Ta, Cr, Mo, W, Mn, Re, Si and Ge.

The present invention further provides a method of forming a single metal damascene structure. An insulating layer is formed on a substrate. An opening is formed in the insulating layer. An alloy layer is formed on a sidewall and a bottom of the opening. The alloy layer includes a first metal and a second metal. A metal filling layer is formed in the opening. An annealing is performed in a nitrogen-containing gas atmosphere, so that the second metal of the alloy layer is nitridated to form a metal nitride layer as a barrier layer.

According to an embodiment of the present invention, the first metal is different from the second metal.

According to an embodiment of the present invention, the first metal is the same as the metal filling layer.

According to an embodiment of the present invention, the first metal includes a copper element or an alloy thereof.

According to an embodiment of the present invention, the second metal includes a titanium (Ti) element or an alloy thereof.

According to an embodiment of the present invention, the nitrogen-containing atmosphere includes nitrogen gas, ammonium gas or a combination thereof.

According to an embodiment of the present invention, the metal filling layer includes a copper element or an alloy thereof.

According to an embodiment of the present invention, the opening includes a contact opening or a via opening

According to an embodiment of the present invention, the method further includes forming a sacrificial layer between the substrate and the insulating layer, and the opening extends into the sacrificial layer.

According to an embodiment of the present invention, the method further includes forming a seed layer between the barrier layer and the metal filling layer.

According to an embodiment of the present invention, the seed layer includes an alloy containing Cu and at least one of Al, Mg, Be, Ca, Sr, Ba, Sc, Y, La, U, Pr, Nd, Sm, Eu, Gd, Tb, Dy, Ho, Er, Tm, Yb, Lu, Hf, V, Nb, Ta, Cr, Mo, W, Mn, Re, Si and Ge.

The single metal damascene structure of the present invention can reduce the contact resistance, prevent the metal from diffusing and enhance the device reliability.

In the present invention, according to the method of forming the said single metal damascene structure, a barrier layer can be formed with simple process steps, metal diffusion can be avoided, and the device reliability can be enhanced.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a cross-sectional view of a single metal damascene structure according to an embodiment of the present invention.

FIGS. 2A to 2D schematically illustrate cross-sectional views of a method of forming a single metal damascene structure according to another embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

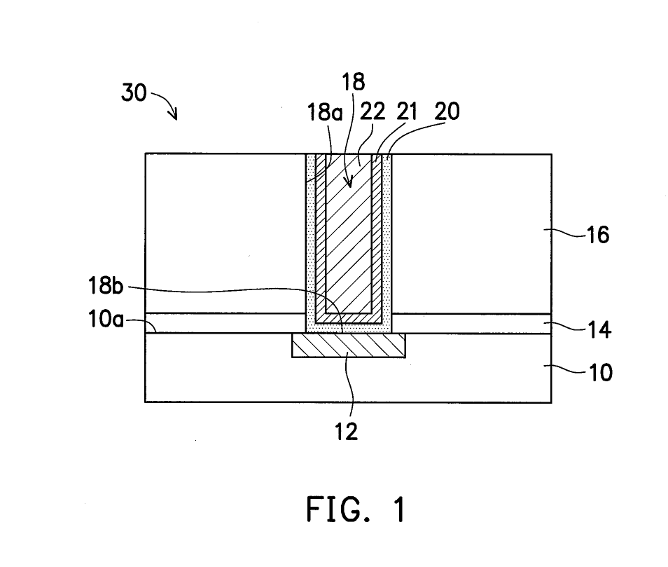

FIG. 1 schematically illustrates a cross-sectional view of a single metal damascene structure according to an embodiment of the present invention.

The single metal damascene structure 30 of the present invention includes a dielectric layer 16, a barrier layer 20, a seed layer 21 and a metal filling layer 22. The dielectric layer 16 has an opening 18 therein, and the opening 18 exposes the conductive region 12. The dielectric layer 16 includes a dielectric material, such as silicon oxide or a low-dielectric-constant (low-k) material with a dielectric constant less than 4. The opening 18 can be a hole extending in a single direction. The single direction can be a direction substantially perpendicular to the surface 10a of the substrate 10. The hole extending in a single direction can be a contact opening or a via opening, for example. In an embodiment, the opening 18 is a contact opening, and the exposed conductive region 12 is a doped region, a metal silicide layer or a gate conductive layer on the substrate 10. The substrate 10 can be a semiconductor substrate or a silicon-on-insulator (SOI) substrate, for example. The doped region can be a source region, a drain region or another region connected to the contact plug. The metal silicide layer can be the one disposed on the source region, the drain region or the polysilicon gate. The metal silicide layer includes tungsten silicide (WSiₓ), titanium silicide (TiSi₂) or cobalt salicide (CoSi₂) or nickel silicide (NiSi₂). The gate conductive layer can be a doped polysilicon layer or a metal silicide layer or a metal gate layer. A sacrificial layer 14 is further included between the dielectric layer 16 and the substrate 10. The sacrificial layer 14 includes silicon nitride, and the forming method thereof includes performing a chemical vapor deposition (CVD) process. In another embodiment, the opening 18 is a via opening, and the exposed conductive region 12 can be a metal line, a wire or a metal layer.

The barrier layer 20 is located on the sidewall 18a and the bottom 18b of the opening 18, between the metal filling layer 22 and the dielectric layer 16, and between the metal filling layer 22 and the conductive region 12. In an embodiment, the barrier layer 20 includes a alloy, and the alloy includes a copper (Cu) element and at least one another metal. The at least one another metal includes a manganese (Mn) element, an aluminium (Al) element or an alloy thereof. The method of forming the barrier layer 20 includes performing a CVD process or a physical vapour deposition (PVD) process.

The seed layer 21 is disposed between the barrier layer 20 and the metal filling layer 22. The seed layer 21 can have the same material as the metal filling layer 22, or can have an alloy containing the material of the metal filling layer 22 and another metal. The seed layer 21 includes an alloy containing Cu and at least one of Al, Mg, Be, Ca, Sr, Ba, Sc, Y, La, U, Pr, Nd, Sm, Eu, Gd, Tb, Dy, Ho, Er, Tm, Yb, Lu, Hf, V, Nb, Ta, Cr, Mo, W, Mn, Re, Si and Ge. The method of forming the seed layer 21 includes performing a CVD process, an electrochemical plating (ECP) process or a PVD process. The seed layer 21 can provide excellent electromigration resistance.

The metal filling layer 22 is located in the opening 18 to cover the barrier layer 20. The metal filling layer 22 includes a tungsten (W) element, a copper element or an alloy thereof The method of forming the metal filling layer 22 includes performing a CVD process, an ECP process or a PVD process.

In an embodiment, the barrier layer 20 of the single metal damascene structure is made of a Cu-Mn alloy. The metal filling layer 22 is made of a tungsten element or an alloy containing tungsten.

In another embodiment, the barrier layer 20 of the single metal damascene structure is made of a Cu-Mn alloy. The metal filling layer 22 is made of a copper element or an alloy containing copper.

In yet another embodiment, the barrier layer 20 of the single metal damascene structure is made of a Cu-Mn-Al alloy. The metal filling layer 22 is made of a copper element or an alloy containing copper.

In still another embodiment, in addition to the single metal damascene structures described above, the barrier layer 20 can be made of a metal nitride conductor, such as titanium nitride. The metal filling layer 22 can be made of a copper element or an alloy containing copper.

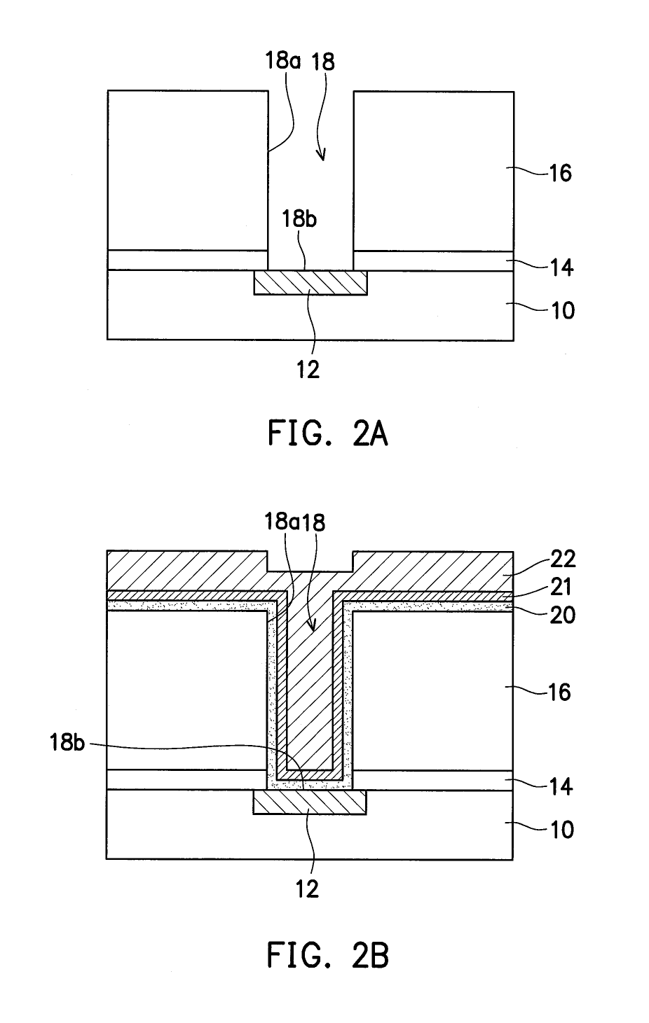

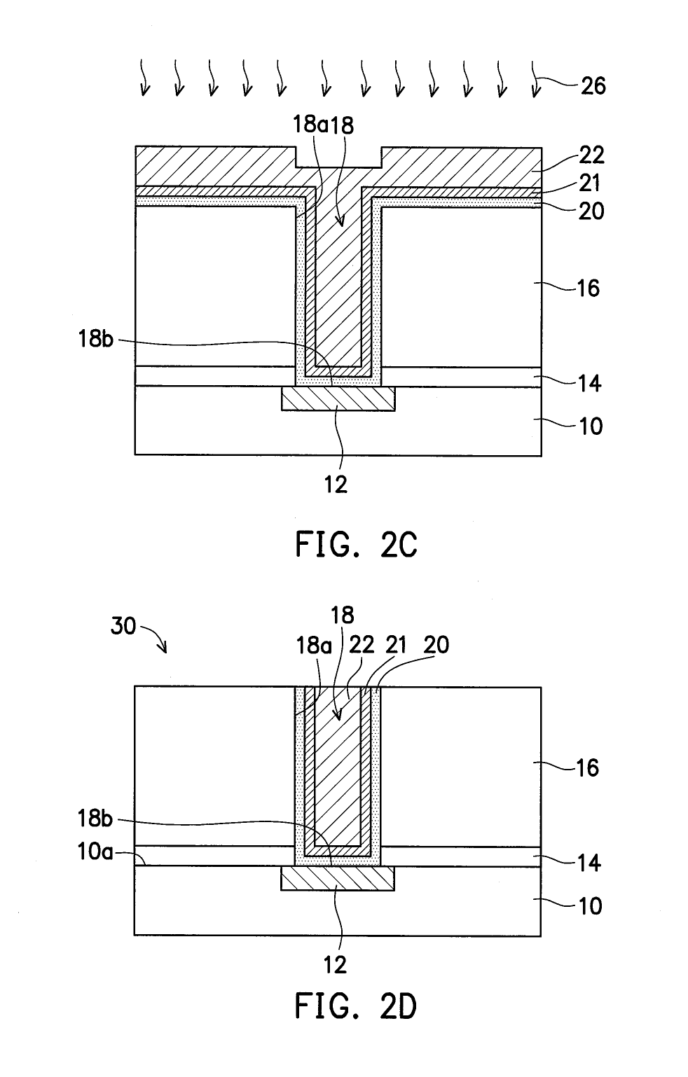

FIGS. 2A to 2D schematically illustrate cross-sectional views of a method of forming a single metal damascene structure according to another embodiment of the present invention. As shown in FIG. 2D, in this embodiment, the barrier layer 20 of the single metal damascene structure can be made of a metal nitride conductor, such as titanium nitride. The metal filling layer 22 can be made of a copper element or an alloy containing copper.

Referring to FIG. 2A, in the method of forming a single metal damascene structure, a substrate 10 having a sacrificial layer 14 and a dielectric layer 16 thereon is provided, and an opening 18 is formed in the sacrificial layer 14 and the dielectric layer 16. The opening 18 exposes a conductive layer 12 on the substrate 10. The opening 18 can be formed through lithography and etching processes. The materials and forming methods of the conductive region 12, the sacrificial layer 14, the dielectric layer 16 and the substrate 10 have been described above, and the details are not iterated herein.

Thereafter, an alloy layer 24 is formed on the sidewall 18a and the bottom 18b of the opening 18. The alloy layer 24 includes a first metal and a second metal. The first metal is different from the second metal. In an embodiment, the first metal is the same as the metal filling layer 22. In another embodiment, the first metal is different from the metal filling layer 22. The first metal includes a copper element or an alloy thereof The second metal includes a titanium (Ti) element or an alloy thereof The method of forming the alloy layer 24 includes performing a CVD process. In an embodiment, the first metal includes a copper element, and the second metal includes a titanium element.

Referring to FIG. 2B, a seed layer 21 and a metal filling layer 22 are formed in the opening 18. The seed layer 21 can have the same material as the metal filling layer 22, or can have an alloy containing the material of the metal filling layer 22 and another metal. The seed layer 21 includes an alloy containing Cu and at least one of Al, Mg, Be, Ca, Sr, Ba, Sc, Y, La, U, Pr, Nd, Sm, Eu, Gd, Tb, Dy, Ho, Er, Tm, Yb, Lu, Hf, V, Nb, Ta, Cr, Mo, W, Mn, Re, Si and Ge. The method of forming the seed layer 21 includes performing a CVD process, an ECP process or a PVD process. The metal filling layer 22 includes a copper element or an alloy containing copper. The method of forming the metal filling layer includes performing a CVD process, an ECP process, or a PVD process.

Referring to FIG. 2C, an annealing 26 is performed in a nitrogen-containing atmosphere, so that the second metal of the alloy layer 24 is nitridated to form a metal nitride layer as a barrier layer 20. The nitrogen-containing atmosphere includes nitrogen gas, ammonium gas or a combination thereof. After the annealing 26 is performed, the first metal of the alloy layer 24 is not nitridated and is fused with the metal filling layer 22 or the seed layer 21.

Referring to FIG. 2D, the metal filling layer 22 on the dielectric layer 16 is removed, and the barrier layer 20, the seed layer 21 and the metal filling layer 22 remaining in the opening 18 serve as a single metal damascene structure. The method of removing the metal filling layer 22 on the dielectric layer 16 includes performing a chemical mechanical polishing (CMP) process.

According to the embodiment of the present invention, the self-forming barrier copper process in the back-end-of-line (BEOL) is introduced to the contact process in the front-end-of-line, and thus, the contact resistance is reduced, metal diffusion is avoided and the device reliability is enhanced.

In summary, the single metal damascene structure of the present invention can reduce the contact resistance, prevent the metal from diffusing and enhance the device reliability.

In the present invention, according to the method of forming the said single metal damascene structure, a barrier layer can be formed with simple process steps and metal diffusion can be avoided.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A single metal damascene structure, comprising:
an insulating layer, having an opening therein;
a metal filling layer, located in the opening; and
a barrier layer, located between the metal filling layer and the insulating layer, wherein the barrier layer comprises an alloy, and the alloy comprises a copper element and at least one another metal.

2. The single metal damascene structure of claim 1, wherein the at least one another metal comprises a manganese (Mn) element, an aluminium (Al) element or an alloy thereof.

3. The single metal damascene structure of claim 1, wherein the opening comprises a contact opening or a via opening.

4. The single metal damascene structure of claim 1, wherein the metal filling layer comprises a tungsten (W) element, a copper element or an alloy thereof

5. The single metal damascene structure of claim 1, further comprising a conductive region on a substrate, the conductive region electrically contacting the barrier layer.

6. The single metal damascene structure of claim 5, wherein the conductive region comprises a metal silicide layer or a doped region.

7. The single metal damascene structure of claim 1, further comprising a seed layer disposed between the barrier layer and the metal filling layer.

8. The single metal damascene structure of claim 7, wherein the seed layer comprises an alloy comprising Cu and at least one of Al, Mg, Be, Ca, Sr, Ba, Sc, Y, La, U, Pr, Nd, Sm, Eu, Gd, Tb, Dy, Ho, Er, Tm, Yb, Lu, Hf, V, Nb, Ta, Cr, Mo, W, Mn, Re, Si and Ge.

9. A method of forming a single metal damascene structure, comprising:
forming an insulating layer on a substrate;
forming an opening in the insulating layer;
forming an alloy layer on a sidewall and a bottom of the opening, wherein the alloy layer comprises a first metal and a second metal;
forming a metal filling layer in the opening; and
performing an annealing in a nitrogen-containing gas atmosphere, so that the second metal of the alloy layer is nitridated to form a metal nitride layer as a barrier layer.

10. The method of claim 9, wherein the first metal is different from the second metal.

11. The method of claim 10, wherein the first metal is the same as the metal filling layer.

12. The method of claim 10, wherein the first metal comprises a copper element or an alloy thereof.

13. The method of claim 10, wherein the second metal comprises a titanium (Ti) element or an alloy thereof.

14. The method of claim 9, wherein the nitrogen-containing atmosphere comprises nitrogen gas, ammonium gas or a combination thereof

15. The method of claim 9, wherein the metal filling layer comprises a copper element or an alloy thereof

16. The method of claim 9, wherein the opening comprises a contact opening or a via opening.

17. The method of claim 9, further comprising forming a sacrificial layer between the substrate and the insulating layer, the opening extending into the sacrificial layer.

18. The method of claim 9, further comprising forming a seed layer between the barrier layer and the metal filling layer.

19. The method of claim 18, wherein the seed layer comprises an alloy comprising Cu and at least one of Al, Mg, Be, Ca, Sr, Ba, Sc, Y, La, U, Pr, Nd, Sm, Eu, Gd, Tb, Dy, Ho, Er, Tm, Yb, Lu, Hf, V, Nb, Ta, Cr, Mo, W, Mn, Re, Si and Ge.
